(19) United States
(12) Patent Application Publication
(10) Pub. No.: US 2021/0389183 A1
(43) Pub. Date: Dec. 16, 2021

(54) HIGH-SPEED ULTRATHIN SILICON-ON-INSULATOR INFRARED BOLOMETERS AND IMAGERS

(71) Applicants: Yale University, New Haven, CT (US); Wisconsin Alumni Research Foundation, Madison, WI (US)

(72) Inventors: Qiushi Guo, New Haven, CT (US); Cheng Li, New Haven, CT (US); Fengnian Xia, Orange, CT (US); Zhenqiang Ma, Madison, WI (US); Dong Liu, Madison, WI (US); Zhenyang Xia, Madison, WI (US)

(73) Assignees: Yale University, New Haven, CT (US); Wisconsin Alumni Research Foundation, Madison, WI (US)

(21) Appl. No.: 17/285,644

(22) PCT Filed: Nov. 8, 2019
(86) PCT No.: PCT/US2019/060482

§ 371 Date: Apr. 15, 2021

Related U.S. Application Data
(60) Provisional application No. 62/758,193, filed on Nov. 9, 2018.

(51) Int. Cl. G01J 3/51; G01J 5/02; H01L 27/146; G01N 21/35; G01J 5/20

(52) U.S. Cl. CPC G01J 3/513; G01J 5/022; H01L 27/14649; G01J 2005/0077; G01J 5/20; H01L 27/1464; G01N 21/35

(57) ABSTRACT

In one aspect, the invention provides a nanobolometer cell including a base layer, a dielectric spacer layer above and adjacent to the base layer, an ultrathin silicon film above and adjacent to the spacer layer, and at least one plasmonic optical antenna resonator above and adjacent to the silicon film.

### CROSS-REFERENCE TO RELATED APPLICATIONS

This application claims the benefit of priority under 35 U.S.C. § 119(e) to U.S. Provisional Patent Application No. 62/758,193, filed Nov. 9, 2018, the contents of which are incorporated by reference herein in their entirety.

### STATEMENT REGARDING FEDERALLY SPONSORED RESEARCH OR DEVELOPMENT

This invention was made with government support under Contract No. 1552461 awarded by the National Science Foundation and under DE-NA0002915 awarded by the Department of Energy. The government has certain rights in the invention.

### BACKGROUND OF THE INVENTION

The mid-infrared (MIR) (2-20 μm) is a critical portion of the electromagnetic spectrum for a host of emerging technologies, devices, and fundamental phenomena. For example, a wide range of molecules and biological materials exhibit strong characteristic vibrational absorption resonances in MIR. The ability to sensitively probe these absorption signatures has far-reaching implications for many applications, including trace gas sensing, non-contact materials characterization and medical diagnostics applications. The MIR wavelength range also covers the thermal emission of most biological and mechanical systems. Therefore, detection of infrared radiation are critical to night vision (imaging based on warm body thermal emissions). In addition, MIR electromagnetic waves can also be used as signal carriers in free space communication due to their relatively weak attenuation in the atmosphere. Being able to replace the current bulky and cryogenically cooled MIR detectors with uncooled compact chip-scale solutions can usher a new era of lower cost, small core MIR sensors, spectrometers, imaging and communication systems that can be widely used in mobile devices.

Despite the technological and scientific importance of the MIR, photodetection in the MIR still poses significant challenges. These challenges are originated from the exceedingly low energy of MIR photons. Conventional MIR photodetectors are usually based on materials with small bandgaps (e.g., HgCdTe, InSb) or inter-sub band transitions in quantum wells to absorb low energy photons and convert it into an electrical signal. These types of detectors almost always require cryogenic cooling because thermionic noise at room temperatures becomes a dominant noise source that blurs the useful signal. The incapability of room temperature operation unfortunately hindered their applications for future chip-scale MIR technologies.

Other approaches to MIR light sensing at room temperature have focused on converting the MIR photon into heat, and then measuring the corresponding output voltage or current change in response to the heat generation. The most prominent example is microbolometer which has been widely used for thermal imaging. However, these types of detectors are not viable for high-speed applications due to the large thermal time constant (milliseconds). Imaging a fast-moving target or a target that is varying temperature swiftly is in general beyond the reach of existing room temperature IR sensors, such as microbolometers, spot pyrometers or thermocouples as they do not have the speed or resolution required for the complete characterization of high-speed thermal applications.

### SUMMARY OF THE INVENTION

In one aspect, the invention provides a nanobolometer cell including a base layer, a dielectric spacer layer above and adjacent to the base layer, an ultrathin silicon film above and adjacent to the spacer layer, and at least one plasmonic optical antenna resonator above and adjacent to the silicon film.

In another aspect, the invention provides an infrared radiation detector including a plurality of the nanobolometer cells. In yet another aspect, the invention includes an infrared imager comprising the detector of the invention.

In yet another aspect, the invention provides a multispectral imager including a plurality of complementary metal-oxide-semiconductor (CMOS) cells and a plurality of nanobolometer cells. In certain embodiments, each of the plurality of nanobolometer cells are interspersed within the CMOS cells.

In certain embodiments, the base layer includes silicon.

In certain embodiments, the dielectric spacer layer defines at least one supporting post extending above and supporting as well as thermally isolating the ultrathin silicon film.

In certain embodiments, the nanobolometer further comprises a back reflector between the silicon base layer and the dielectric spacer layer. In certain embodiments, the back reflector is a highly conductive metal. In certain embodiments, the highly conductive metal is selected from the group consisting of gold, silver, copper, and aluminum.

In certain embodiments, the dielectric spacer layer includes one or more selected from the group consisting of: silicon dioxide and silica aerogel.

In certain embodiments, the ultrathin silicon film is doped with one or more selected from the group consisting of: boron, phosphorus, arsenic and gallium.

In certain embodiments, the at least one plasmonic optical antenna resonator is selected from the group consisting of: a metallic nanoparticle, a metal-silicon nanoparticle, a gold plasmonic resonator, a silver plasmonic resonator, a copper plasmonic resonator, a nanorod, a nanoshell, a nanoplate, a solid nanoshell, a hollow nanoshell, a nanorice, a nanosphere, a nanofiber, a nanowire, a nanopyramid, a nanoprism, and a nanostar. In certain embodiments, the metallic nanoparticle and the metal-silicon nanoparticle comprises a metal selected from the group consisting of: silver, gold, nickel, copper, titanium, palladium, platinum, and chromium.

In certain embodiments, the ultrathin silicon film has a thickness of 5 nm-50 nm.

In certain embodiments, the nanobolometer cell is operationally connected to a readout integrated circuit.

In certain embodiments, the nanobolometer cell has a high response speed of at least 50 MHz (20 ns).

In certain embodiments, the nanobolometer cell is operational at room temperature and does not require cooling.

In certain embodiments, the multispectral imager includes the plurality of nanobolometer cells of the invention. In certain embodiments, the multispectral imager is a front-illuminated silicon multispectral imager. In certain other embodiments, the multispectral imager is a back-illuminated silicon multispectral imager.

### BRIEF DESCRIPTION OF THE DRAWINGS

For a fuller understanding of the nature and desired objects of the present invention, reference is made to the following detailed description taken in conjunction with the accompanying drawing figures wherein like reference characters denote corresponding parts throughout the several views.

FIGS. 1A-1C depict silicon-on-thermal-insulator (SOTI) sub-wavelength mid-infrared plasmonic nanobolometers including an ultrathin silicon active layer and a thermal insulation layer.

FIGS. 2A-2C depicts optical design of plasmonic structures for broadband mid-infrared light adsorption. FIG. 2A is a cross-sectional view of the unit cell of a metal-insulator-metal (MIM) cavity including a plasmonic optical antenna resonator, a dielectric λ/4 spacer (silica aerogel in this example) and a metallic back reflector. FIG. 2B is a top view of the designed plasmonic structures. FIG. 2C is simulated infrared absorption and reflection spectra of the designed plasmonic structure using a commercial software (LUMERICAL FDTD™ 2018a).

FIG. 3 depicts a preliminary fabricated device structure with Au plasmonic resonators deposited on ultrathin single-crystal silicon film (UTSF). The left panel is an optical image of the fabricated device. The right panel is a false-colored scanning electron microscopy (SEM) image of the structure, in which the yellow colored regions represents the Au plasmonic resonators. The ultrathin silicon nanomenbrane (NM) was etched in to nanoribbons in order to minimize the regions that are not heated by Au plasmonic resonators.

FIGS. 4A-4C depict Noise Equivalent Temperature Difference (NETD) estimation. FIG. 4A is a 3D view of the temperature distribution of the device unit pixel (6×6 μm²). 50 μm silica aerogel with thermal conductivity of 0.04 W/mK was assumed in the simulation. ˜6 K temperature rise in ultrathin silicon is caused by an incident IR light power density of 1×10⁴ W/m². The corresponding incident IR power on the pixel is 360 nW. The absorption of Au plasmonic resonator was assumed to be 45%. FIG. 4B is a top view of the simulation result shown in FIG. 4A. FIG. 4C is a chart depicting estimated ΔT and NETD of 6×6 μm² pixel vs. the aerogel thermal conductivity. Simulations were performed using commercial COMSOL® software.

FIG. 5A depicts a silicon-on-thermal-insulator (SOTI) sub-wavelength mid-infrared plasmonic nanobolometer including an ultrathin silicon active layer and metallic light absorber on a silicon dioxide thermal insulation layer with supporting posts for the ultrathin silicon active layer.

FIG. 5B depicts a thermal equivalent circuit within the nanobolometer.

FIG. 6 depicts exemplary locations of supporting posts within the nanobolometer.

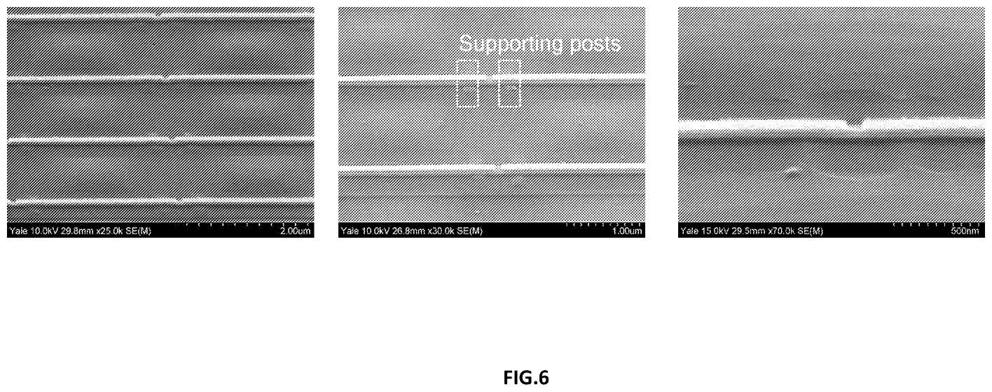

FIG. 7 is a table comparing a nanobolometer according to an embodiment of the invention with conventional microbolometers.

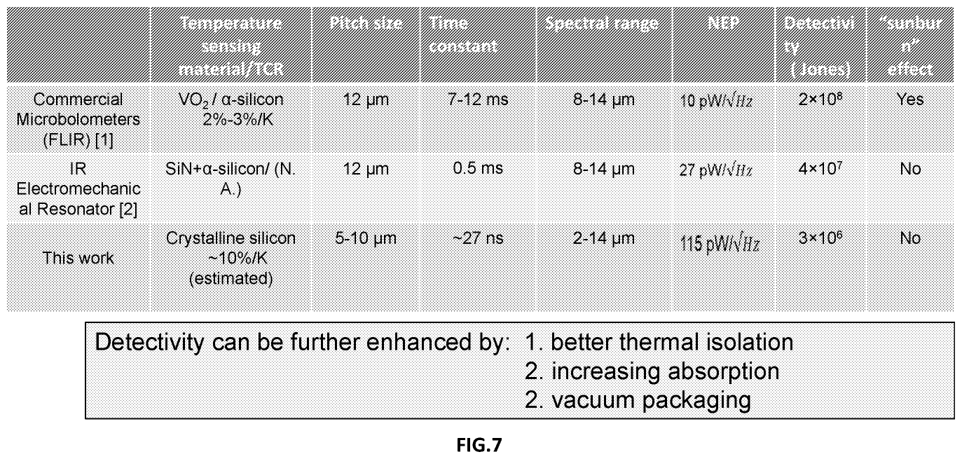

FIG. 8 depicts a design for a front-illuminated silicon multispectral imager.

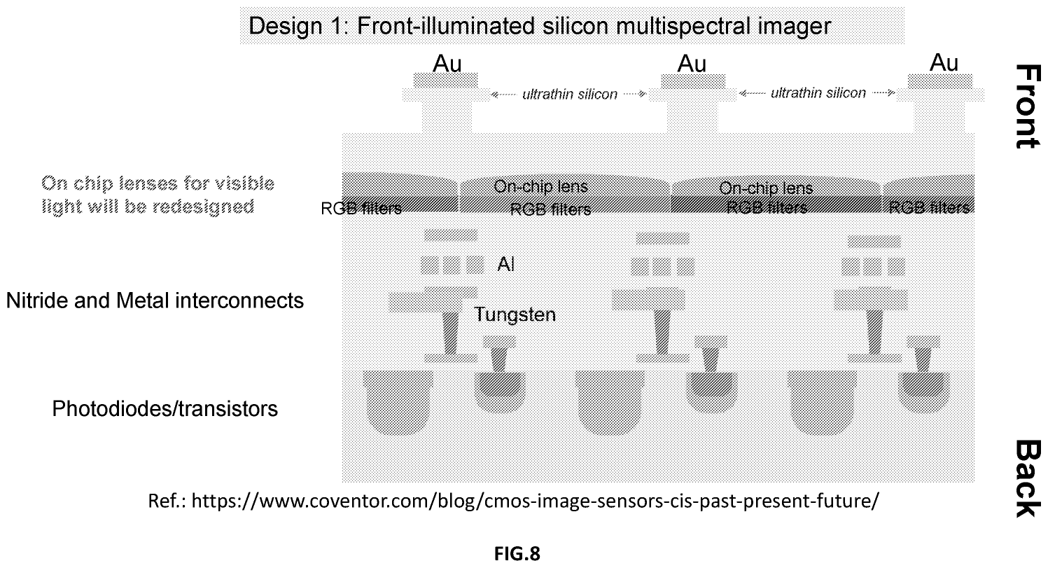

FIG. 9 depicts a design for a back-illuminated silicon multispectral imager.

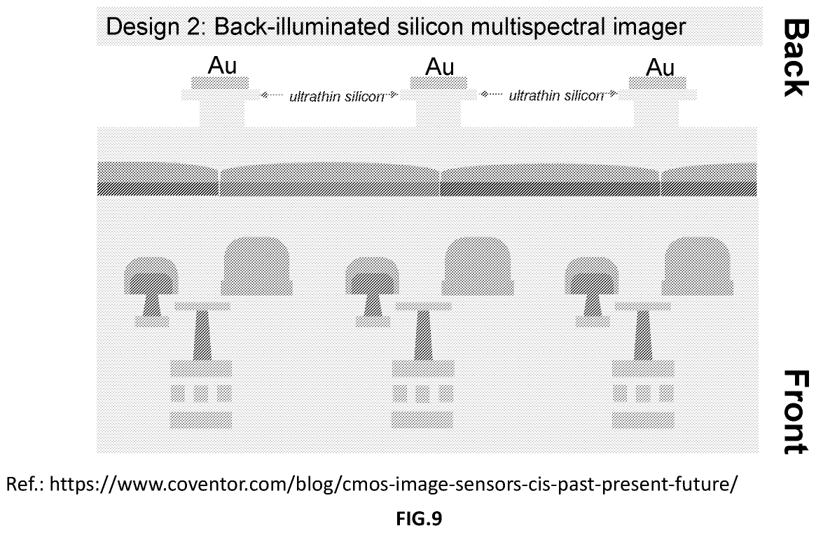

FIG. 10 show an arrangement of long wavelength MIR infrared pixels (LWMIR) embedded among the visible imaging/NIR pixels.

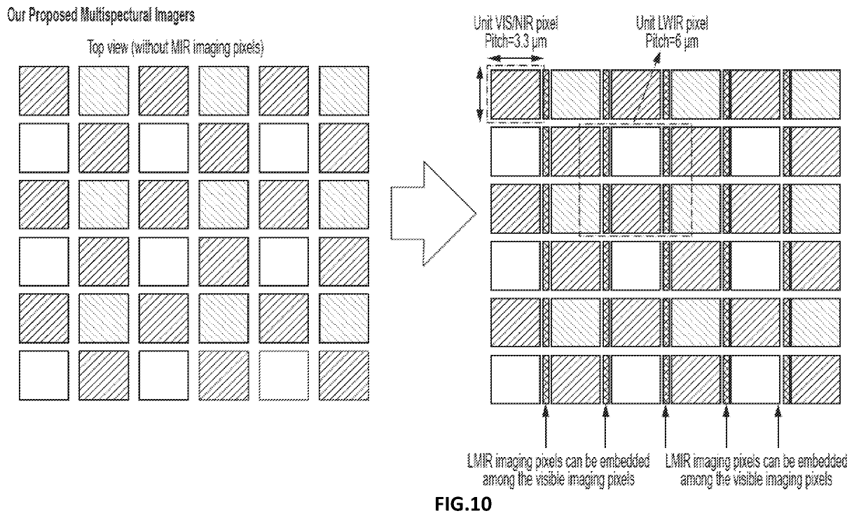

FIG. 11A is image of an aerogel AIRLOY® X56 procured from www.buyaerogel.com/product/airloy-x56/.

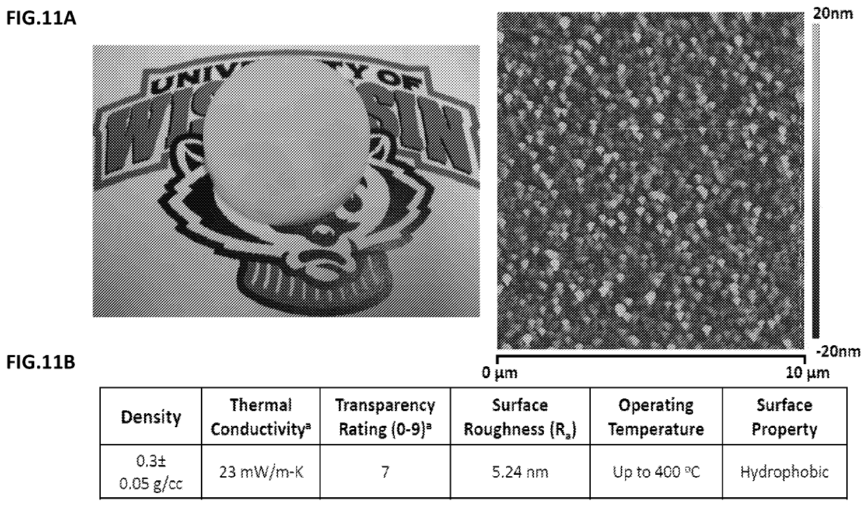

FIG. 11B is a table listing various physical and chemical properties of the aerogel shown in FIG. 11A.

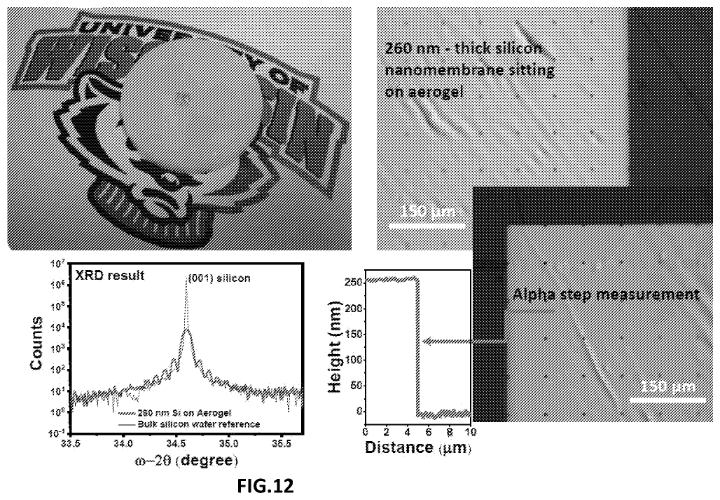

FIG. 12 is an image showing silicon (Si) nanomembrane transferred onto the surface of the aerogel.

FIG. 13 depicts graphs for results of TCR testing of intrinsic Si nanomembrane. The subthreshold regime offers the highest signal noise ratio (large resistance) and highest TCR.

FIG. 14 depicts a photomask design for doping of the Si nanomembrane.

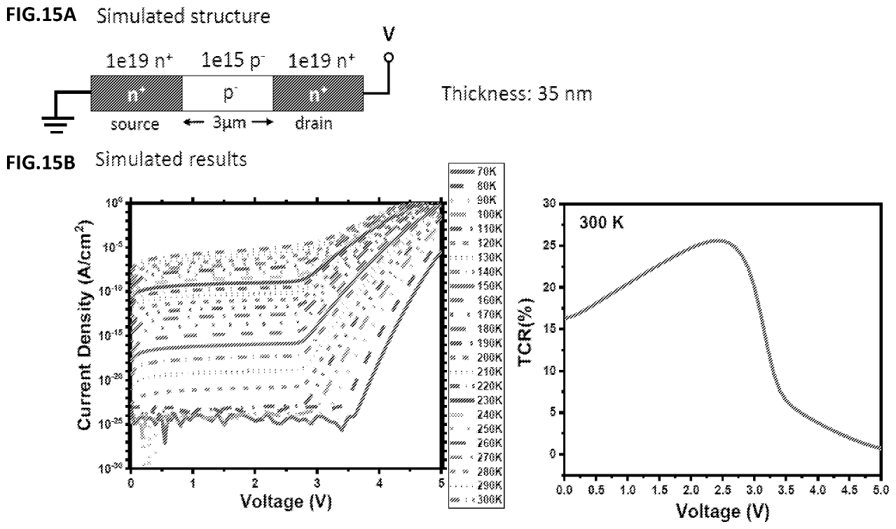

FIGS. 15A-15B depicts designing of the Si nanomembrane. FIG. 15A shows simulated structure of Si nanomembrane. FIG. 15B shows simulated results for Si nanomembrane.

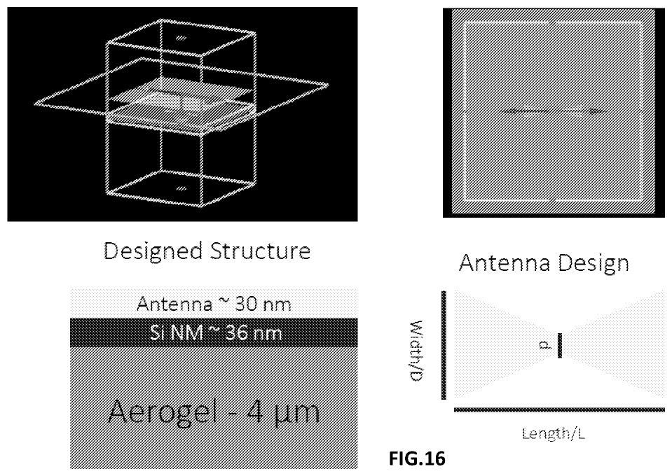

FIGS. 16-17 depict design, fabrication, and measurements related to the metallic antenna.

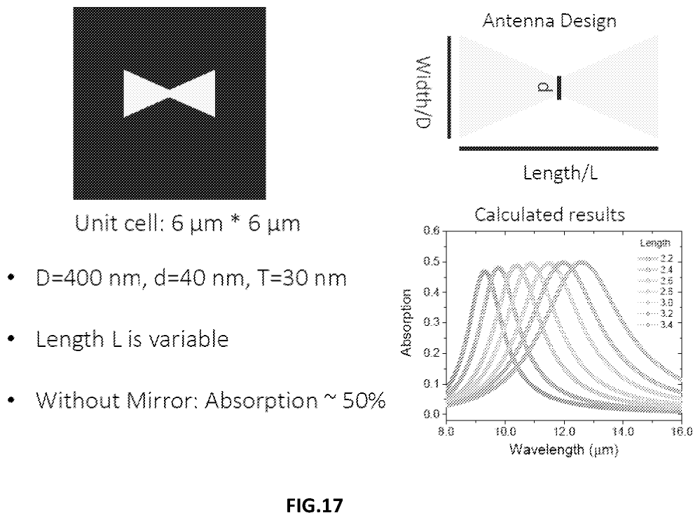

FIGS. 18A-18B show antenna design. FIG. 18A shows antenna on diamond-like-carbon on bulk silicon. FIG. 18B is a set of spectra showing extinction values for the antennas having different lengths.

FIG. 19 are spectra showing that due to the use of bulk silicon substrate, the array of antennas with periodicity of 6 μm×6 μm show reduced absorption compared to the array of antennas with periodicity of 6 μm×4 μm.

FIG. 20 shows that, for antenna, the experimental absorption matches well with the theoretically calculated absorption and that high absorption in mid-infrared is achieved.

FIG. 21 shows a set-up for bolometer's noise measurement. A shielded box will be used for measuring bolometer's electric noise.

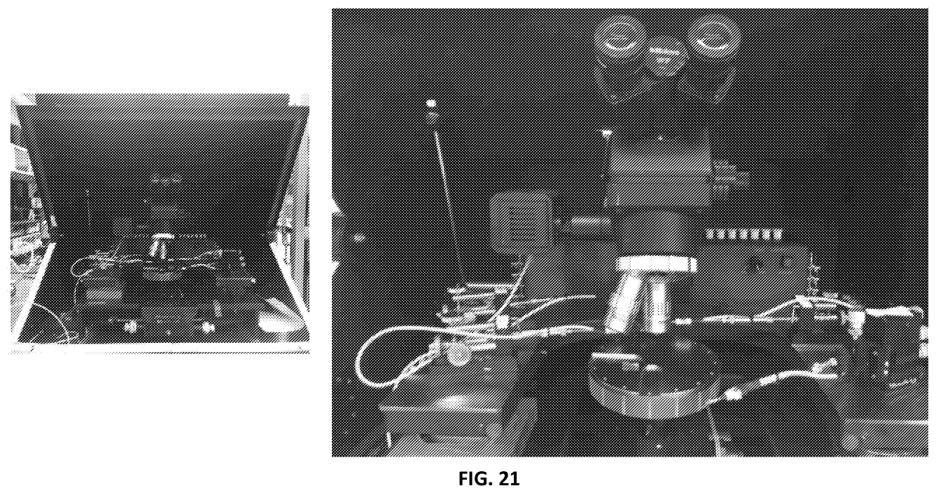

FIG. 22 shows a top view of spiral design for the antenna.

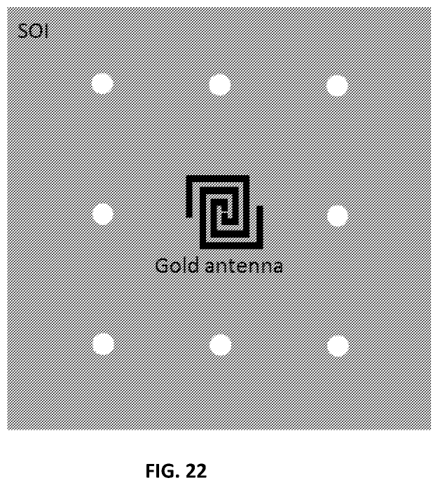

### DEFINITIONS

The instant invention is most clearly understood with reference to the following definitions.

As used herein, the singular form “a,” “an,” and “the” include plural references unless the context clearly dictates otherwise.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from context, all numerical values provided herein are modified by the term about.

As used in the specification and claims, the terms “comprises,” “comprising,” “containing,” “having,” and the like can have the meaning ascribed to them in U.S. patent law and can mean “includes,” “including,” and the like.

Unless specifically stated or obvious from context, the term “or,” as used herein, is understood to be inclusive.

As used herein, the term “μm” is the abbreviation for “micron” or “micrometer”, and it is understood that 1 μm=0.001 mm=10⁻⁶ m=1 millionth of a meter.

As used herein, the term “nanodevice” refers to a device that has at least one component with at least one spatial dimension less than 1 micron.

As used herein, the term “nm” is the abbreviation for “nanometer” and it is understood that 1 nm=1 nanometer=10⁻⁹ m=1 billionth of a meter.

Ranges provided herein are understood to be shorthand for all of the values within the range. For example, a range of 1 to 50 is understood to include any number, combination of numbers, or sub-range from the group consisting 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 (as well as fractions thereof unless the context clearly dictates otherwise).

### DETAILED DESCRIPTION OF THE INVENTION

There is a pressing need for a high-sensitivity, high-bandwidth infrared bolometer. These include all-weather MIR light detection and ranging systems (MIR LIDAR), thermal imaging technologies to resolve the motion of fast-moving objects, free space communications, etc.

As building blocks of room temperature mid-infrared (MIR) imager, microbolometers have had pixel-pitch progressively scaled down from 50 μm to 12 μm in the past twenty years. State-of-the art room temperature microbolometers have a minimum pixel size of around 12×12 μm² and the noise equivalent temperature difference (NETD) is about 100 milli-Kelvin (mK). However, it is highly desirable to further reduce the pixel size in order to achieve much improved imaging performance, which is highly desirable for many defense applications. For example, the detection range of many of today's uncooled IR imaging systems is limited by pixel resolution. By downscaling the pitch size, and thereby upscaling the pixel number of detectors, the detection range increases significantly. At the same time, it is of critical importance to maintain its sensitivity while scaling down. In conventional microbolometer, the reduction in pixel size inevitably led to a smaller absorbed infrared-power-per-unit-pixel. Since the thermal conductance of each pixel hardly varies during the pixel scaling, the actual temperature rise becomes smaller for a smaller pixel. Therefore, it is known that the NETD is almost inversely proportional with the pixel area. Moreover, in traditional microbolometers, the operational speed is low (<100 Hz) due to the large heat capacity of the IR absorbing material. Overall, there is little room for engineering the thermal conductance in order to achieve a lower NETD. As discussed above, one key step toward achieving a low NETD in a sub-wavelength nanobolometer is to design a structure with small heat capacity such that the device thermal conductance can be aggressively reduced to achieve a low NETD while also maintaining a high device operational speed. At the same time, large infrared absorption and large temperature coefficient of resistance (TCR) play an equally important role.

Embodiments of the invention provide plasmonically enabled long-wavelength mid-infrared (LWIR) nanobolometer based on ultrathin silicon-on-insulator film. The nanobolometer operates at room temperature, offering high signal-to-noise ratio concurrently with high speed. Briefly, the incident infrared electromagnetic power is first absorbed in the plasmonic optical antenna resonator resulting in efficient heating of the plasmonic optical antenna resonator and the suspended silicon film underneath. The thermally activated carrier transport in silicon offers a sensitive readout of the temperature elevation in the structure.

Further embodiments of the invention encompass a multispectral imager that can capture both visible and mid-infrared images simultaneously.

### Nanobolometer Cell

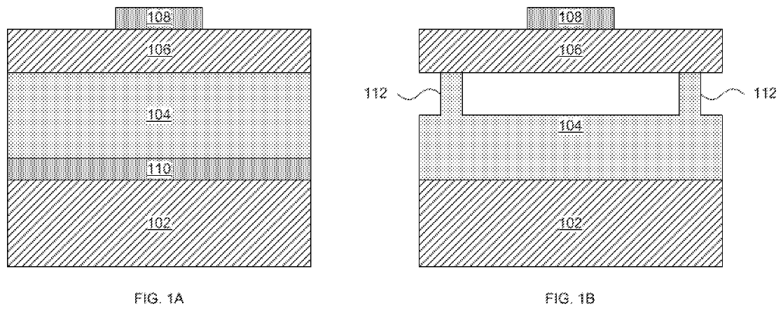

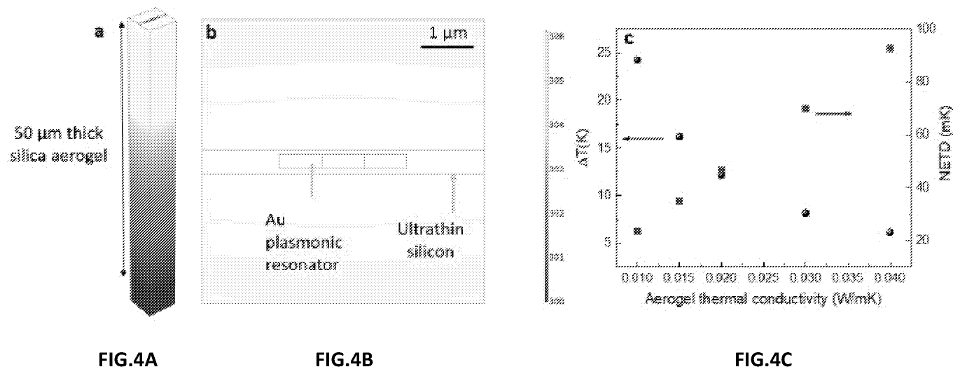

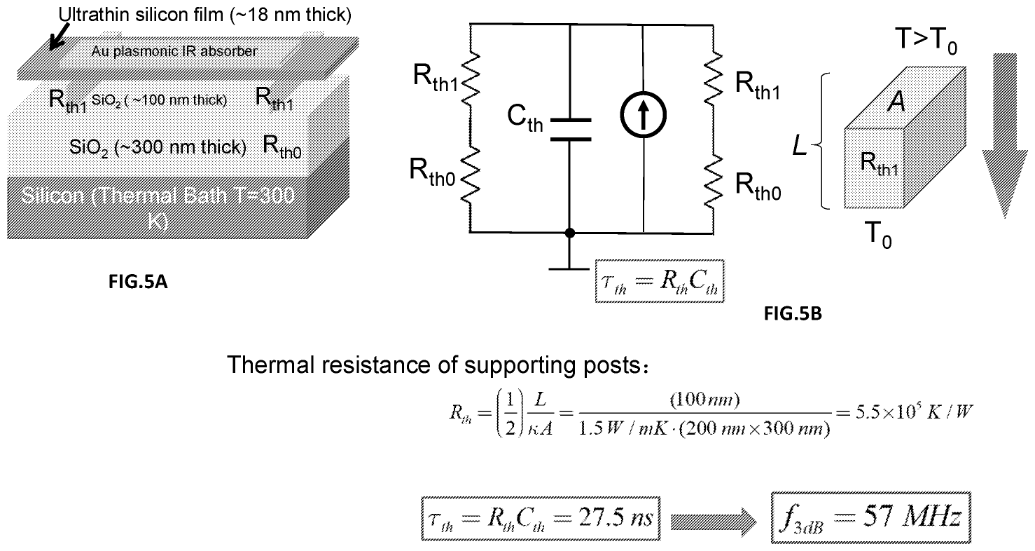

Referring to FIGS. 1A and 1B, in one aspect, an embodiment of a nanobolometer cell 100 includes a base layer 102, a dielectric spacer 104 layer above and adjacent to the base layer 102, an ultrathin silicon film (UTSF) doped with boron or other dopants 106 above and adjacent to the spacer layer 104; and at least one plasmonic optical antenna resonator 108 above and adjacent to the ultrathin silicon film 106. Referring to FIGS. 1A, 1B, and 5A, two exemplary configurations of a nanobolometer cell are shown.

The at least one plasmonic optical antenna resonator 108 absorbs IR (e.g., MIR, near-infrared, and/or long-infrared) radiation and increase the local electromagnetic field density. In certain embodiments, the at least one plasmonic optical antenna resonator 108 is selected from the group consisting of a metallic nanoparticle, a metal-silicon nanoparticle, a gold plasmonic resonator, a silver or a copper plasmonic resonator, a nanorod, a nanoshell, a nanoplate, a solid nanoshell, a hollow nanoshell, a nanorice, a nanosphere, a nanofiber, a nanowire, a nanopyramid, a nanoprism, and a nanostar. In certain embodiments, the at least one plasmonic optical antenna resonator 108 has a Diabolo antenna geometry. In certain embodiments, the at least one plasmonic optical antenna resonator 108 has a spiral antenna geometry.

Plasmonic nanoparticles are available from a variety of sources including nanoComposix of San Diego, Calif. Exemplary materials include gold, silver, silica, platinum, titania, magnetite. For example, nanoparticles can be solid or hollow (e.g., gold-silica nanoshells having a silica core surrounded by a gold shell). Plasmonic nanoparticles can be tuned to have a desired absorption spectra and/or peak wavelength absorption by specifying materials and dimensions, using formulas such as the Mie theory or software available from sources such as COMSOL, and can be purchased to meet desired specifications. Plasmonic nanoparticles and phenomena are further described, for example, in Nanoplasmonics (Grégory Barbillon ed. 2017).

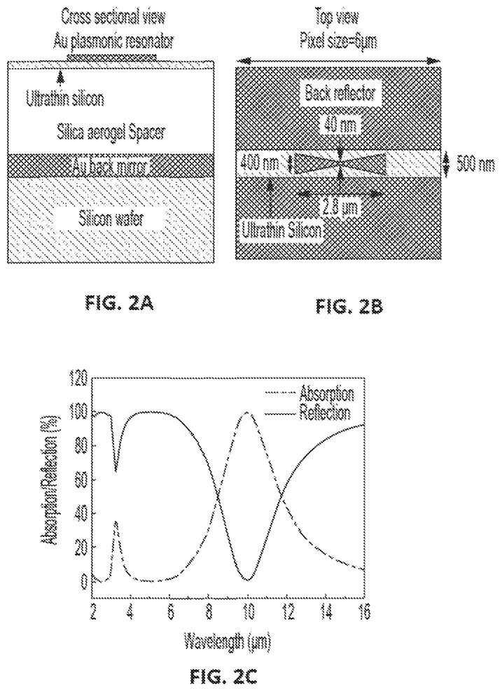

In an exemplary embodiment and as shown in FIG. 3, the at least one plasmonic optical antenna resonator 108 is a gold (Au) nanorod having a length of ˜2.7 μm. In certain embodiments, the absorption band of the at least one plasmonic optical antenna resonator 108 can be tailored from near-IR to far-IR regime by simply adjusting the dimensions of the at least one plasmonic optical antenna resonator 108.

In certain embodiments, the at least one plasmonic optical antenna resonator 108 is operably connected with the UTSF 106 such that with the incident MIR radiation, the electrons in the at least one plasmonic optical antenna resonator 108 heat up and transfer their thermal energy to the UTSF 106, thereby elevating the temperature of the UTSF 106. The temperature change causes a corresponding change in the resistivity, which is monitored by readout circuitry (ROIC), one example of which is described and depicted in S. Liu et al, “A design of readout circuit for 384×288 uncooled microbolometer infrared focal plane array”, Proc. 2012 IEEE 11th International Conference on Solid-State and Integrated Circuit Technology (2012). In certain embodiments, the thickness of the UTSF 106 ranges from 5 nm to 50 nm. In certain embodiments, a dopant is optionally added to the UTSF 106. In certain embodiments, the dopant is selected from the group consisting of boron, phosphorus, arsenic and gallium. In an exemplary embodiment, the UTSF 106 is ˜20 nm in thickness and is a crystalline silicon that is boron-doped with a very low doping concentration of about 10¹³ cm⁻³.

In certain embodiments, the ultrathin silicon layer 106 is deposited on a dielectric spacer layer 104, thereby forming a silicon-on-insulator (SOI) wafer. The dielectric spacer layer 104 thermally isolates the UTSF 106 from the base layer 102 (constant temperature heat sink). Due to the thermal isolation, the silicon active layer 106 has a significant temperature elevation in response to MIR radiation compared to the base layer 102, imparting higher sensitivity to the nanobolometer cell 100. In certain embodiments, the dielectric spacer layer 104 is a continuous layer.

In certain other embodiments depicted in FIGS. 1B and 5A, the dielectric spacer layer 104 defines at least one supporting post 112 extending above and supporting and thermally isolating the ultrathin silicon film 106.

In certain embodiments, the thickness of the dielectric spacer layer 104 varies from about 200 nm to 450 nm. In certain embodiments, the height of the supporting posts varies from about 50 nm to 300 nm. In an exemplary embodiment, and as shown in FIG. 5A, the thickness of the dielectric layer 104 is ˜300 nm and the height of the supporting post 112 is ˜300 nm. In certain embodiments, a dielectric spacer layer 104 includes one or more selected from the group consisting of silicon dioxide, silica aerogel, Al₂O₃, and HfO₂.

In certain embodiments, varying the thickness of the dielectric spacer layer affects the NETD value associated with the spacer layer. For example, the NETD values for aerogel having thickness of about 10 μm, 20 μm, and 50 μm were calculated (from simulations) to be about 145, 121, and 97.6 mK, respectively.

In certain embodiments, the base layer 102 is a heat sink or a thermal bath with large thermal mass and has a constant temperature. In an exemplary embodiment, the temperature of the base layer is maintained, for example, at 300K. In certain embodiments, the base layer 102 includes silicon.

In certain embodiments, the nanobolometer cell 100 includes a back reflector 110 that reflects optical radiation back towards the antenna(s) 108. In certain embodiments, the back reflector 100 is a highly conductive metal, which can optionally be polished to form a mirror. In certain embodiments, the highly conductive metal is selected from the group consisting of gold, silver, copper, and aluminum.

In certain embodiments, a unit pixel size of the nanobolometer cell varies from about 5×5 μm² to about 10×10 μm².

In an exemplary embodiment and as shown in FIG. 5A, the plasmonic optical antenna resonator is an Au nanorod and the pixel has a pitch of 2.8 μm. The length of Au nanorod is 2.7 μm and the spacing between nanorods is 100 nm. The total absorbance of Au nanorod array is ˜30%. The unit pixel has two metal contacts for electronic readout. Part of buried oxide underneath the top silicon active layer is undercut by buffered oxide etchant (BOE) wet etching in order to thermally isolate the thin silicon layer and the substrate, because the substrate is regarded as the thermal bath with large thermal mass and its temperature is almost unchanged. The gap between the top silicon layer and the oxide is about 100 nm. For each unit pixel cell, the total thermal resistance between the active silicon layer and the substrate is estimated to be 5.5×10⁵K/W. Due to the ultra-small volume, the overall heat capacity of Au and ultrathin silicon nanostructures is ˜5×10¹⁴ J/K. The ultra-small heat capacity of suspended nanostructures together with the thermal resistance give rise to a thermal time constant of 27 ns, which is about six orders of magnitudes smaller than the existing microbolometer technologies.

The net current change at the contacts before and after exposure to MIR radiation is proportional to the temperature of the silicon active layer or the intensity of incident MIR radiation. This net current change is then amplified by a low-noise current amplifier and the resulting voltage is used as a measure of incident infrared power. By sweeping the back-gate voltage from ˜100 V to 100 V and fixing the bias voltage at the two metal contacts, the device exhibits an ambipolar transport characteristic. In addition, the device operating regime can be continuously tuned from high resistivity (R>1 GΩ) to low resistivity regime (R˜1 MΩ). After the thermal isolation, the responsivity, defined as the net current change divided by the incident IR power, is increased by 30 times compared to the device without thermal isolation. This results in a peak current responsivity of 5×10⁻⁵ A/W, which can be translated to a voltage responsivity of 71 V/W at the low resistivity regime and a Johnson noise limited noise equivalent power of 600 pW/√Hz. The device offers the best signal-to-noise ratio in the high resistivity regime, with a Johnson noise limited noise equivalent power down to of 300 pW/√Hz. The photoresponse of the nanobolometer device does not show any reduction when the IR modulation frequency is tuned from 10 Hz to 200 KHz, which is limited by the measurement setup described herein.

### Multispectral Imager

In another aspect, the invention is a multispectral imager including a plurality of complementary metal-oxide-semiconductor (CMOS) cells and a plurality of nanobolometer cells. The plurality of nanobolometer cells are interspersed within the CMOS cells. This enables measurement of both visible light and infrared (or other spectra inducing surface plasmons within the antennae 108).

In certain embodiments, each of the plurality of nanobolometer cells is the cell as described embodiments enlisted supra, herein. In certain embodiments, the multispectral imager is a front-illuminated silicon multispectral imager. In certain other embodiments, the multispectral imager is a back-illuminated silicon multispectral imager.

Embodiments of the invention can be incorporated within a variety of devices seeking to detect heat (e.g., from mechanical, electrical, or biological systems such as animals and/or humans). Exemplary applications include all-weather MIR light detection and ranging systems (MIR LIDAR), thermal imaging technologies to resolve the motion of fast-moving objects, free space communications, etc. Other examples, include forward-looking infrared cameras for military, aircraft, law enforcement, maintenance, and medical applications. In still another embodiment, nanobolometers according to embodiments of the invention can be incorporated within automobiles to detect animals and pedestrians in support of self-driving or accident-avoidance systems.

### EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the compounds of the present invention and practice the claimed methods. The following working examples therefore, specifically point out the preferred embodiments of the present invention, and are not to be construed as limiting in any way the remainder of the disclosure.

### PROPHETIC EXAMPLES

### General Methods

### Example 1: Wafer-Scale Transfer of Ultrathin Silicon onto Aerogel

The wafer-scale (4″) deposition of thick silica aerogel thermal insulating layer and a scheme of transferring large-scale (cm in size) ultrathin silicon onto the aerogel will be developed. Aerogel is very porous and extremely light. Aerogel has a very low thermal conductivity due to its porous nature. Silica aerogel is known to offer ultralow thermal conductivity of ranging from 0.01 to 0.04 W/mK. The spray coating process (Hrubesh, Lawrence W., and John F. Poco. Journal of non-crystalline solids 188.1-2 (1995): 46-53), which has been used to deposit thick aerogel coatings on substrates such as glass and silicon wafers will be employed. Aerogel films as thick as 80 μm have been achieved previously by this method. (Kimberly A. D. Obrey and Roland K. Schulze. 20th Target Fabrication Meeting Santa Fe, N. Mex. Tuesday, May 22, 2012). Specifically, as reported Hrubesh et al., an aspirator will be used to deposit precursor onto the substrates. The gel will be formed after the solution drains. One advantage of aerogel for device fabrication is its smooth surface. Supercritical drying can be useful in the formation of aerogel (Tewari, Param H., Arlon J. Hunt, and Kevin D. Lofftus. Materials Letters 3.9-10 (1985): 363-367).

### Example 2: Optical Design of Plasmonic Structures for Broadband Mid-Infrared Light Adsorption

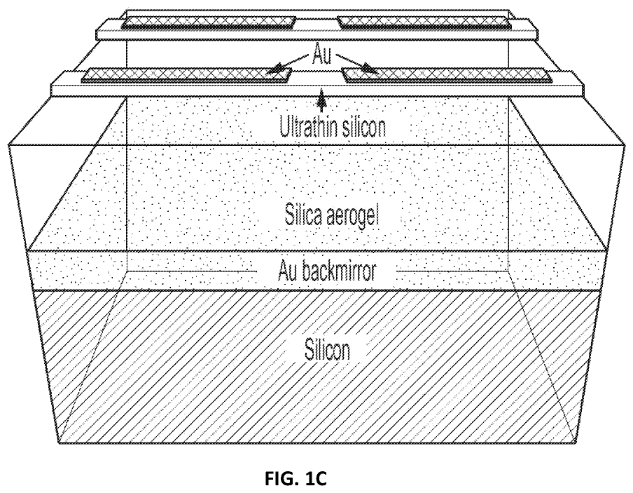

Metal plasmonic nanostructures to achieve >50% of light absorption across the entire 8 to 12 μm range will be designed. The metal-insulator-metal (MIM) optical cavity which consists of a plasmonic optical antenna resonator, a dielectric spacer (silica aerogel in this case) and a metallic back reflector will be employed. When the back reflector is thick enough to strongly reflect the light and cavity length is close to λ/4, near unity absorption of optical radiation can be achieved in the plasmonic optical antenna. The previously reported Diabolo antenna geometry (Coppens, Zachary J., et al. Nano Letters 13.3 (2013): 1023-1028) is one of the geometry that will be used as a plasmonic resonator in order to further enhance the heat generation and the temperature increase in the antenna structure due to infrared light absorption. The device geometry is shown in FIGS. 2A and 2B. Using the FDTD electromagnetic wave solver (LUMERICAL FDTD™ 2018a), the simulated absorption and reflection spectra are shown in FIG. 2C, in which near 100% absorption at λ=10 μm in the plasmonic resonator with the λ/4 cavity is obtained. Experimentally, the total reflectance (R) and transmittance (T) of the device will be measured using the Fourier transformed infrared spectroscopy (FTIR). The absorption will be then be calculated by 1−R−T. Here, with the thick Au mirror, the transmittance (T) is expected to be close to 0. Besides the design shown in FIG. 2B, other geometries will also be explored.

It is noted that ˜100% peak absorption is possible only when the length of the cavity is properly designed. The cavity length may be thicker than λ/4 to achieve optimal thermal insulation. As a result, the peak absorption may not reach 100%. However, it is expected that the peak absorption can be >50%. Also explored will be the design consisting of more than one nanostructures to extend the bandwidth such that the absorption can be greater than 50% across the entire 8 to 12 μm range.

### Example 3: Proof-of-Concept Device Fabrication

The proof-of-concept devices will be fabricated. Two different fabrication routes will be leveraged. In the first route, the ultrathin silicon bolometers (before the last dry etch step for the formation of the silicon sub-micron ribbons) will be first fabricated and then the device will be transferred to the aerogel with low thermal conductivity. After the transfer, dry-etch will be performed to define the bolometer device. In the second approach, ultrathin silicon onto aerogel will be first transferred and then the bolometers will be fabricated.

In both cases, the general fabrication steps are summarized as follows. (1) First e-beam or photolithography step on ultrathin silicon to define the gold (Au) plasmonic resonators and e-beam evaporation of Au of 25 nm, followed by metal lift-off (2) Second lithography step to define the metal contact region. The ion-implantation will be used to reduce the contact resistance of the contact region. Thick metal will be deposited onto the contact region followed by lift-off. (3) Third lithography step defining the etched silicon region to minimize the regions which are not heated. (4) Etching of silicon by reactive ion etching (ME). The remaining resist is then stripped by oxygen plasma. In the first route, steps (1) and (2) will be finished and then the thin silicon nanomembrane (NM) together will be transferred with metal contacts onto aerogel. The final two steps then define the silicon active region. In the second route ultrathin silicon will be transferred onto aerogel and all fabrication steps (1) to (4) will be performed on the aerogel. To further reduce the thermal conductivity of the device, the aerogel directly is selectively etched directly underneath the Au nanostructure and characterize the device in vacuum.

A preliminary fabricated structure is shown in FIG. 3, in which Au plasmonic resonators will be fabricated on ultrathin silicon nanoribbons, which are patterned from an ultrathin single crystal silicon thin film (UTSF). A suspended silicon nanomembrane will be fabricated and a back gate will be used to tune the silicon doping concentration to optimize device performance. This device schematic makes it a three terminal device. The ultrathin silicon is further doped with various dopants and different doping concentrations to optimize device performance.

### Example 4: Device Characterization and NETD Estimation

The temperature coefficient of resistance (TCR) of the device, extrinsic responsivity, detector bandwidth up to 50 MHz and the noise of the device at its peak response (10 μm) will be measured. The noise equivalent power (NEP) will be calculated. Furthermore, based on the device geometry, the NETD of the device will be calculated.

First, the device extrinsic responsivity (Rₑₓₜ) at its peak response wavelength (10 μm) will be measured. The expression of Rₑₓₜ is Rₑₓₜ=Iₚₕ/P_{inc}, where Iₚₕ is the measured photocurrent in unit of Ampere and P_{inc} is the actual incident light power on the pixel in unit of Watt. Second, the detector bandwidth can be obtained by AC-modulating the infrared laser and monitoring the photocurrent reduction. Third, the frequency dependent current noise amplitude will be measured and the noise amplitude within 1 Hz bandwidth will be determined. By using the low-noise current amplifier, the background current fluctuations δIₙ in the device will be converted (amplified) into measurable voltage fluctuations δVₙ and will be acquired by the lock-in amplifier. Then, by analyzing the frequency components of δVₙ from 1 Hz to above 100 kHz, one can plot the δIₙ (in unit of A/√Hz) as a function of frequency by using the relation

$${I}_{n} = \frac{δ {V}_{n}}{G} ,$$

in which G is the gain factor of the low noise current amplifier. It is expected that at higher frequency (>10 kHz), the noise of the detector would be dominated by Johnson noise, which is of lower amplitude and frequency independent due to the reduction of 1/f noise. The device noise within 1 Hz bandwidth (δIₙ) will be determined as the noise amplitude at the frequency right before the 3 dB cut-off frequency of the device.

Given the measured Rₑₓₜ and δI, the NEP as NEP=δIₙ/Rₑₓₜ, will be calculated, which is in the unit of in unit of W/√Hz. Then the NETD is calculated as (Laurent, Ludovic, et al. Physical Review Applied 9.2 (2018): 024016):

$$N E T D = \frac{4 {F}^{2}}{π A {ϕ ( \frac{Δ L}{Δ T} )}_{300 K}} N E P$$

where F is the optical aperture (usually F=1), A is the pixel surface area, and ϕ and

$${( \frac{Δ L}{Δ T} )}_{300 K}$$

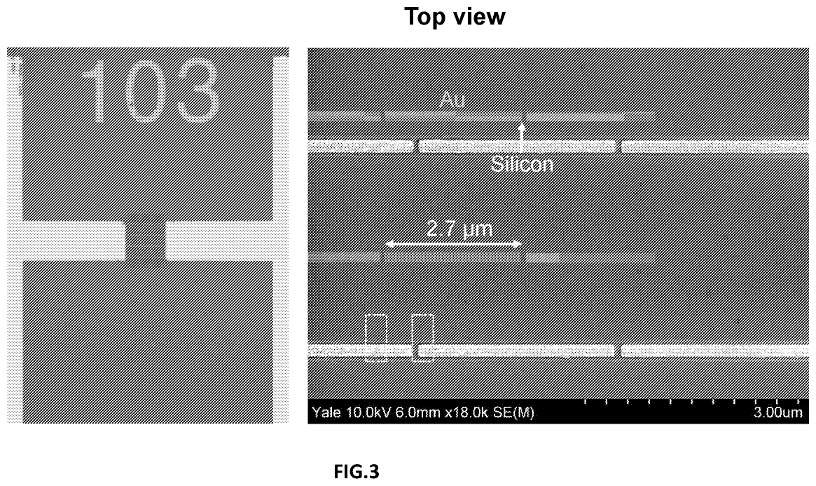

are the optical transmission and the luminance variation with the scene temperature around 300 K, respectively. Φ is usually close to 1, and (ΔL/ΔT)_{300K} is evaluated as 0.84 W/m²/sr/K (Laurent, Ludovic, et al. Physical Review Applied 9.2 (2018): 024016). FIG. 4C shows an estimated temperature rise (ΔT) and NETD of 6×6 μm² device assuming the noise is dominated by Johnson noise. Also, assumed is that the infrared absorption is 45% and the thickness of silica aerogel is 50 μm. In the estimation, the ΔT is caused by an incident IR light power density of 1×10⁴ W/m². The corresponding incident IR power on the pixel (6×6 μm²) is 360 nW. Assuming the TCR of UTSF is 5%, an NETD below 50 mK can be realized if the thermal conductivity of the 50 μm thick aerogel is below 0.02 W/mK.

### EXPERIMENTAL EXAMPLES

### Example 5: Transfer of Ultrathin Silicon onto Aerogel

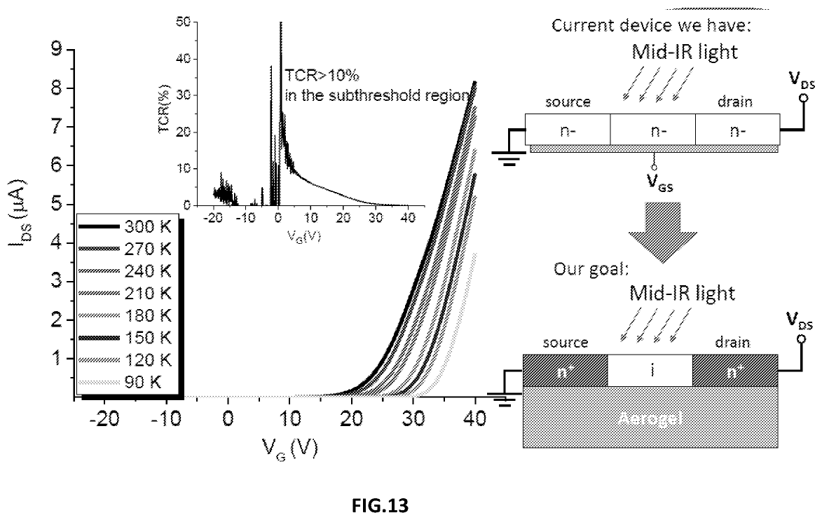

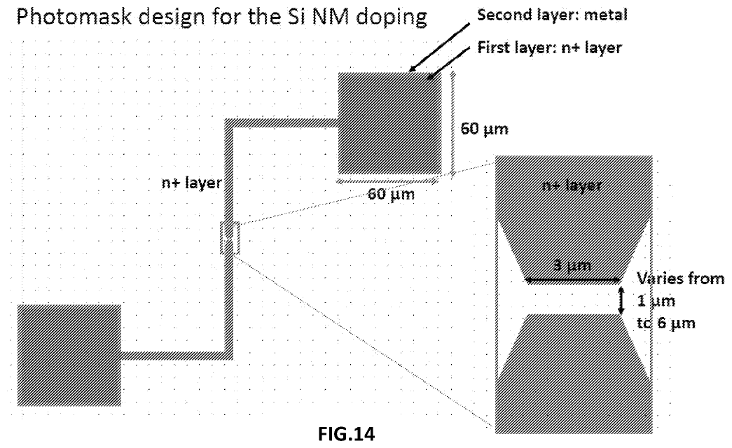

As shown in FIG. 12, a silicon nanomembrane having thickness of about 260 nm was successfully deposited on an aerogel substrate. FIG. 13 shows the results from TCR testing of intrinsic silicon (Si) nanomembrane. The subthreshold regime offers the highest signal:noise ratio (large resistance) and highest TCR.

### Example 6: Antenna Design, Fabrication and Measurements

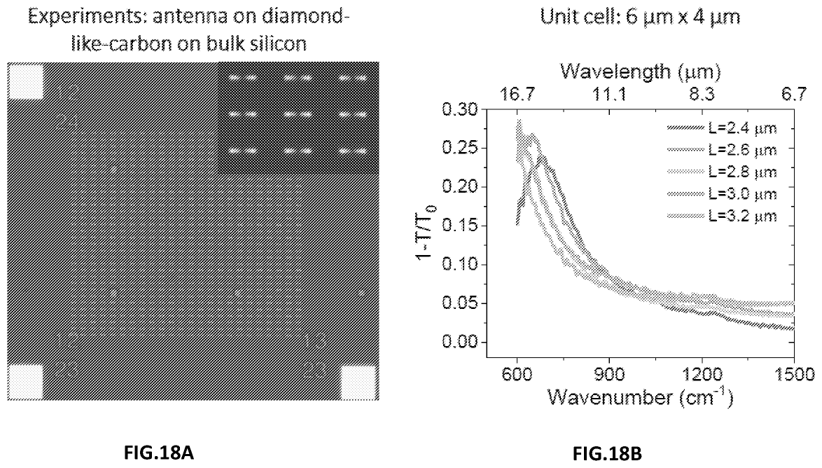

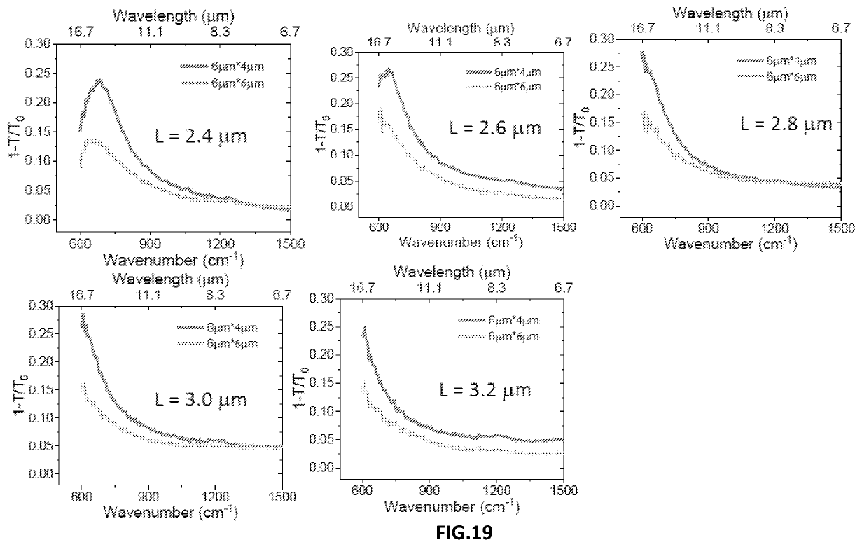

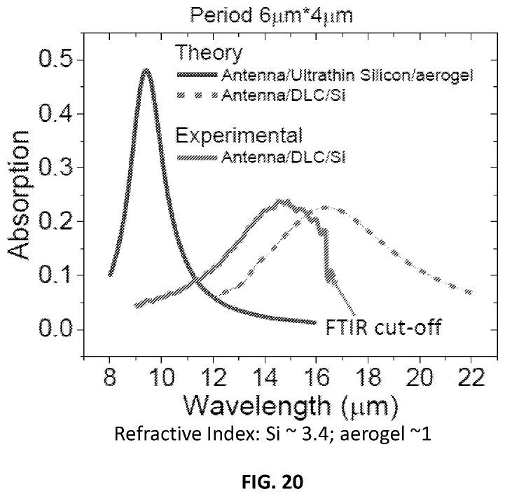

FIG. 18A shows an image for antenna design, wherein the antennas are on diamond-like-carbon on bulk silicon. FIG. 18B is a set of spectra showing that the extinction is up to 30% for array of antennas, wherein the unit cell size is 6 μm×4 μm. FIG. 19 shows that the array of antennas with periodicity of 6 μm×6 μm exhibit reduced absorption compared to the array with periodicity of 6 μm×4 μm. The reduction in absorbance is due to the presence excess of bulk silicon substrate. Further, FIG. 20 shows that the experimental value for absorption by the antenna in mid-infrared region is comparable to the theoretically calculated value.

### EQUIVALENTS

The recitation of a listing of elements in any definition of a variable herein includes definitions of that variable as any single element or combination (or subcombination) of listed elements. The recitation of an embodiment herein includes that embodiment as any single embodiment or in combination with any other embodiments or portions thereof.

The disclosures of each and every patent, patent application, and publication cited herein are hereby incorporated herein by reference in their entirety. Although preferred embodiments of the invention have been described using specific terms, such description is for illustrative purposes only, and it is to be understood that changes and variations may be made without departing from the spirit or scope of the following claims.

1. A nanobolometer cell comprising:
a base layer;
a dielectric spacer layer above and adjacent to the base layer;
an ultrathin silicon film above and adjacent to the spacer layer; and
at least one plasmonic optical antenna resonator above and adjacent to the silicon film.

2. The nanobolometer cell of claim 1, wherein the base layer comprises silicon.

3. The nanobolometer cell of claim 1, wherein the dielectric spacer layer defines at least one supporting post extending above and supporting and thermally isolating the ultrathin silicon film.

4. The nanobolometer cell of claim 1, further comprising a back reflector between the silicon base layer and the dielectric spacer layer.

5. The nanobolometer cell of claim 4, wherein the back reflector is a highly conductive metal.

6. The nanobolometer cell of claim 5, wherein the highly conductive metal is selected from the group consisting of gold, silver, copper, and aluminum.

7. The nanobolometer cell of claim 1, wherein the dielectric spacer layer comprises one or more selected from the group consisting of: silicon dioxide and silica aerogel.

8. The nanobolometer cell of claim 1, wherein the ultrathin silicon film is doped with one or more selected from the group consisting of: boron, phosphorus, arsenic and gallium.

9. The nanobolometer of claim 1, wherein the at least one plasmonic optical antenna resonator is selected from the group consisting of: a metallic nanoparticle, a metal-silicon nanoparticle, a gold plasmonic resonator, a silver plasmonic resonator, a copper plasmonic resonator, a nanorod, a nanoshell, a nanoplate, a solid nanoshell, a hollow nanoshell, a nanorice, a nanosphere, a nanobowtie, a nanofiber, a nanowire, a nanopyramid, a nanoprism, and a nanostar.

10. The nanobolometer of claim 9, wherein the metallic nanoparticle and the metal-silicon nanoparticle comprises a metal selected from the group consisting of: silver, gold, nickel, copper, titanium, palladium, platinum, and chromium.

11. The nanobolometer cell of claim 1, wherein the ultrathin silicon film has a thickness of 5 nm-50 nm.

12. The nanobolometer cell of claim 1, wherein the nanobolometer cell is operationally connected to a readout integrated circuit.

13. The nanobolometer cell of claim 1, wherein the nanobolometer cell has a high response speed of at least 50 MHz (20 ns).

14. The nanobolometer cell of claim 1, wherein the nanobolometer cell is operational at room temperature and does not require cooling.

15. An infrared radiation detector comprising a plurality of the nanobolometer cell of claim 1.

16. An infrared imager comprising the detector of claim 15.

17. A multispectral imager comprising
a plurality of complementary metal-oxide-semiconductor (CMOS) cells; and
a plurality of nanobolometer cells;
wherein each of the plurality of nanobolometer cells are interspersed within the CMOS cells.

18. The multispectral imager of claim 16, wherein the plurality of nanobolometer cells are according to claim 1.

19. The multispectral imager of claim 17, wherein the multispectral imager is a front-illuminated silicon multispectral imager.

20. The multispectral imager of claim 17, wherein the multispectral imager is a back-illuminated silicon multispectral imager.
